(19) United States
(12) Patent Application Publication
(10) Pub. No.: US 2006/0223243 A1
(43) Pub. Date: Oct. 5, 2006

(54) Carbon nanotube - metal contact with low contact resistance

(76) Inventors: Marko Radosavljevic, Beaverton, OR (US); Justin Brask, Portland, OR (US); Suman Datta, Beaverton, OR (US); Amlan Majumdar, Portland, OR (US); Robert S. Chau, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/095,829

(22) Filed: Mar. 30, 2005

(51) Int. Cl. H01L 21/84; H01L 21/00

(52) U.S. Cl. 438/149

(57) ABSTRACT

A metal to Carbon nanotube contact region is described that comprises a chemical bond between the metal and the Carbon nanotube.

### FIELD OF INVENTION

The field of invention relates generally to the electronic arts; and, more specifically, to Carbon nanotube-metal contact with low contact resistance.

### BACKGROUND

FIG. 1a shows a simple model for a field effect transistor (FET) 100. An FET typically has three terminals 101, 102, 103 and is typically viewed as having two basic modes of operation: “linear”; and, “saturation”. Both the linear and velocity saturation regions are observed in the exemplary FET transfer characteristics that are presented in FIG. 1b.

According to a perspective of an FET's linear and saturation regions of operation, the first terminal 101 is used to influence the number of carriers that are present within a conductive channel 104. The current through the conductive channel 104 is approximately proportional to the number of these carriers multiplied by their effective velocity through the conductive channel 104.

Over the course of the FET's “linear” region of operation, which is approximately region 105 of FIG. 1b, a voltage established across the second and third terminals 102, 103 (V₂₃) determines the current that flows through the conductive channel (I₂₃). By contrast, over the course of the FET's “saturation” region of operation, which is approximately region 106 of FIG. 1b, the current I₂₃ that flows through the conductive channel 104 is essentially “fixed” because the conductive channel's ability to transport electrical current is “saturated” (e.g., the velocity of the conductive channel's carriers reach an internal “speed limit”).

Traditionally, one of terminals 102 and 103 is called a “source” and the other of terminals 102 and 103 is called a “drain”. Because the conductive channel 104 is traditionally made of a different material than either of electrodes 102 and 103, resistances R₂ and R₃ are typically associated with the “contact” that exists between the electrode material and the conductive channel material. As such, each of resistances R₂ and R₃ are often referred to as “contact resistance”.

Generally, the contact resistances R₂ and R₃ are regarded as unwanted because the larger these resistances become the less efficiently the FET will operate. For example, in the case of the linear region of operation 105, the larger the R₂ and R₃ resistances become the less current will flow through the conductive channel for a specific V₂₃ voltage. In the case of the saturation region of operation 106, the larger the R₂ and R₃ resistances become the greater the V₂₃ voltage will be even though the I₂₃ current is fixed to a specific value.

Thus, considerable engineering effort has been extended over the history of transistor device development to reduce source/drain contact resistance.

### FIGURES

The present invention is illustrated by way of example and not limitation in the figures of the accompanying drawings, in which like references indicate similar elements and in which:

FIG. 1a (prior art) shows a model of a field effect transistor;

FIG. 1b (prior art) shows exemplary transfer device characteristics for a field effect transistor;

FIG. 2 shows a field effect transistor having a carbon nanotube conductive channel and a low source/drain contact resistance;

FIG. 3 shows a methodology for forming a field effect transistor having low source/drain contact resistance;

FIG. 4 shows data obtained for fabricated CNT/metal contacts.

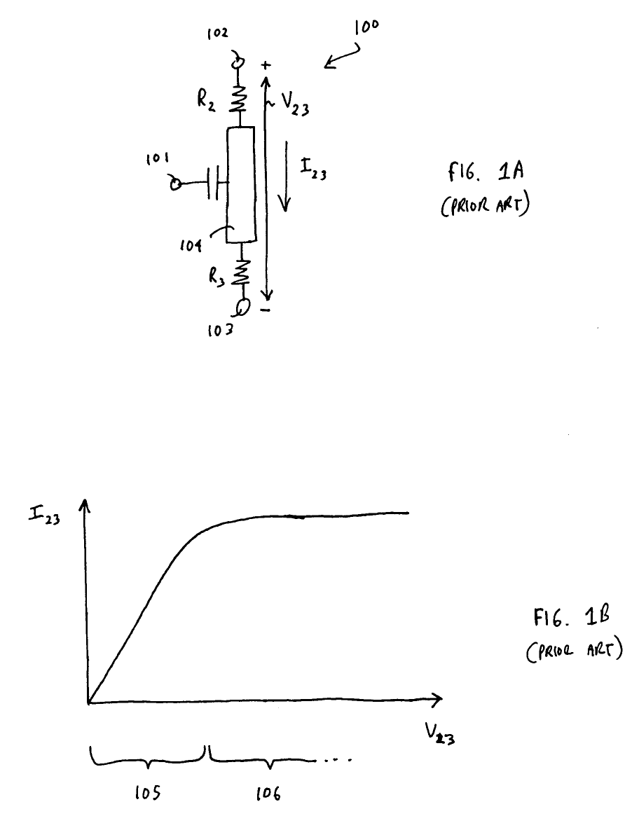

### DETAILED DESCRIPTION

A Carbon nanotube (CNT) can be viewed as a sheet of graphite (also known as graphene) that has been rolled into the shape of a tube (end capped or non-end capped). CNTs having certain properties (e.g., a “conductive” CNT having electronic properties akin to a metal) may be appropriate for certain applications while CNTs having certain other properties (e.g., a “semiconducting” CNT having electronic properties akin to a semiconductor) may be appropriate for certain other applications. CNT properties tend to be a function of the CNT's “chirality” and diameter. The chirality of a CNT characterizes its arrangement of carbon atoms (e.g., arm chair, zigzag, helical/chiral). The diameter of a CNT is the span across a cross section of the tube.

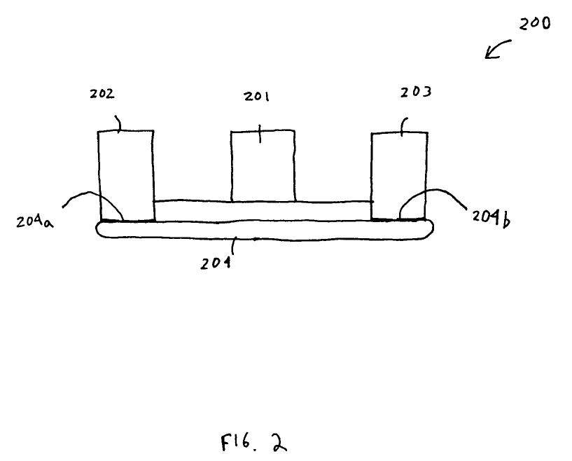

FIG. 2 shows a basic outline for a transistor designed to use a carbon nanotube 204 as its conductive channel. According to the transistor design of FIG. 2, a source electrode 202 makes contact to a carbon nanotube 204 at contact region 204a, and, a drain electrode 203 makes contact to carbon nanotube 204 at contact region 204b. The transistor also includes a gate electrode 201. The carbon nanotube 204 typically has electrical conducting properties sufficient for the gate node electrode 201 to be used as a basis for influencing the number of charge carriers that appear in the carbon nanotube 204 so that the magnitude of the current that flows through the carbon nanotube can be modulated at the gate node 201.

A problem with transistors that use carbon nanotubes is that the contact resistance at contact regions 204a and 204b is too large. The source/drain contact resistance of transistors designed with carbon nanotube conductive channels is particularly troublesome for two reasons. Firstly, carbon nanotubes are extremely small and contact resistance is inversely proportional to the surface area through which current flows. Secondly, carbon nanotubes can often be viewed as “inert” items of matter that have limited potential for chemical reaction.

With respect to the first problem described above, resistance is inversely proportional to the surface area through which current flows. Since the surface area over which a contact to a carbon nanotube can be made is extremely small (owing to the sheer minuteness of the carbon nanotube itself), the contact resistance to a carbon nanotube is apt to be high simply because of the miniscule dimensions that are involved. As such, heavy emphasis may need to be directed at addressing the second problem discussed above if contact resistance is to be sufficiently reduced.

With respect to the second problem described above, electrical current generally corresponds to a “flow” of carriers such as free electrons or “holes” (where a hole is the absence of an electron). The less strident the barriers to carrier flow within a unit of volume and/or the greater the density of carriers within the unit of volume, the more conductive the unit of volume will be. Within the confines of the Carbon nanotube itself, a conducting or semi-conducting Carbon nanotube tends to exhibit sufficiently small barriers to carrier flow and/or sufficiently high carrier densities such that appreciable currents are sustained.

Across the boundaries of a carbon nanotube, however, the situation can be different. According to one perspective, carrier flow in and/out of a carbon nanotube is related to the nanotube's propensity to chemically react with neighboring atoms or molecules (on the theory that electrical current is related to electron flow and a chemical reaction involves an exchange and/or sharing of electrons), and, Carbon nanotubes can be viewed, at least in certain circumstances, as being “inert” or having only a limited propensity to react with atoms or molecules that are in contact with the Carbon nanotube. The fact that Carbon nanotubes do not exhibit a strong natural oxide supports this perspective. Additionally, the fact that a Carbon nanotube can be viewed as stable sheet of graphite that “rolls back on itself” suggests that the Carbon atoms in a Carbon nanotube prefer to “interact” with each other rather than atoms or molecules external to the Carbon nanotube.

Here, it is believed that Carbon nanotubes have no chemically unsatisfied bonds which would at least partially explain their inert-like characteristics. As such, prior art metal/nanotube contacts are believed to be quasi-mechanical in nature (e.g., formed through physisorbtion) which suggests electron transfer across the contact region is not accomplished “with ease”. Electrical current flow in and out of a Carbon nanotube is therefore more strained than electrical current flow within the Carbon nanotube itself; which, in turn, corresponds to high source/drain contact resistance in a transistor that is formed with a Carbon nanotube conductive channel—irrespective of the small dimensions that are involved.

A “treatment” that enhances a Carbon nanotube's propensity to react with a conductive material that is in contact with the nanotube should therefore help to reduce the contact resistance between the conductive material and the Carbon nanotube.

Accordingly, it is has been found that treatment of a metal/nanotube contact region with an oxidizing agent solution of near neutral pH (such as a “weak” acid) can be used to lower the contact resistance of the contact region, because, it is believed, the oxidizing agent effectively “eats away” at the Carbon nanotube surface so as to create imperfections in the nanotube's chirality structure (e.g., dislocations, dangling or empty (unsatisfied) bonds, etc.). The creation of these imperfections essentially corresponds to the creation of chemically unsatisfied bonds on the nanotube's surface that are eventually satisfied, in some fashion, through chemical bonding with the contact metal. Because chemical bonding of the Carbon nanotube with the contact metal is believed to correspond to some kind of electron transfer or sharing between the nanotube and the contact metal, it is likewise believed that the inducement of such chemical bonding should result in an easier flow of electrons across the contact junction, and, correspondingly, lower contact resistance through the contact junction.

According to a preferred approach, the oxidizing agent solution that a junction between a Carbon nanotube and a conductive material is treated with is “weakly reactive” so that “too much” damage is not induced to the Carbon nanotube. For example, the eating away at the surface of a single-walled Carbon nanotube would essentially form openings in the Carbon nanotube. Too many such openings could cause the Carbon nanotube to disintegrate to the point that it is no longer useful. Generally, it is believed that the more walls a Carbon nanotube has, the less such disintegration of the Carbon nanotube there will be (e.g., a dual walled Carbon nanotube may be subjected to longer treatment and/or to a stronger oxidizing agent concentration than a single walled Carbon nanotube). An oxidizing agent is understood to be the substance in an oxidation-reduction that gains electrons. An oxidizing agent solution is understood to be a solution that contains an oxidizing agent.

According to one perspective, an oxidizing agent solution having a pH level within a range of 6.0-8.0 inclusive is sufficient for Carbon nanotubes of 1.2-1.6 nm in diameter of all chiralities and independent of length. Potentially, larger tubes (such as multi-walled or metallic CNTs) should be more robust so they could withstand a larger pH range (e.g., 4.0 to 10.0 inclusive).

According to a particular embodiment, an oxidizing agent solution is made from a solution of 5% hydrogen peroxide (H₂O₂) in water. This solution produces a pH level of about 7.4. In a further embodiment, the hydrogen peroxide that is used in the solution is “pure” in the sense that it does not contain various chemicals (e.g., stabilizers, such as acetanilide) used to preserve the shelf life of the hydrogen peroxide. Here, pure hydrogen peroxide does not have a long “shelf-life”. As such, commercially available forms of hydrogen peroxide often contain certain “foreign” chemicals to lengthen the shelf life of the hydrogen peroxide. According to a specific embodiment, the hydrogen peroxide that is used to form the oxidizing agent solution does not contain any such chemicals.

Furthermore, according to this embodiment, the oxidizing agent described above is applied to a nanotube/metal contact region for about 2 minutes at 24° C. The oxidizing agent is then rinsed from the contact region with de-ionized water. Isopropanol Alcohol (IPA) is then applied to the contact region and permitted to evaporate. At a high level, this approach can be viewed as applying an oxidizing agent solution to a metal/nanotube contact region for only a brief period of time in order to essentially cause “controlled damage” to the surface of the Carbon nanotube; where, unsatisified bonds are created but the usefulness of the Carbon nanotube is not destroyed. Generally, the treatment time for application of an oxidizing agent solution should be about 1.0-5.0 minutes for oxidizing agent solutions having a pH level within a range of 6.0-8.0 inclusive.

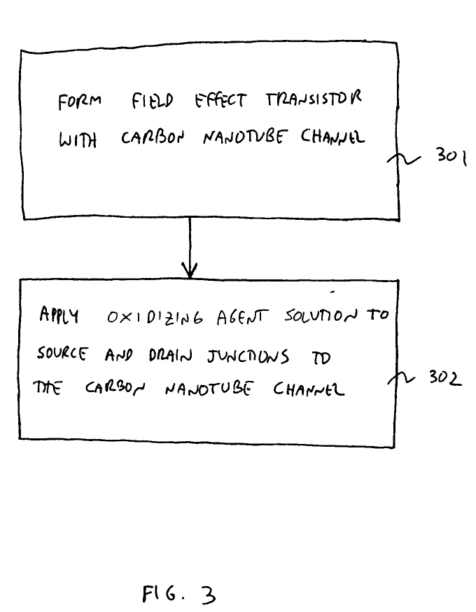

FIG. 3 shows a flow diagram for the basic methodology s related to transistor fabrication. According to the diagram of FIG. 3, a field effect transistor having a carbon nanotube channel is formed 301; then, an oxidizing agent solution is applied 302 to the source drain contact regions (junctions) in order to reduce their contact resistance. In an embodiment, the transistor need not be fully formed prior to application of the oxidizing agent solution. For example, the source/drain regions may be developed at least up to the point of the application of the oxidizing agent prior to completion of the gate electrode.

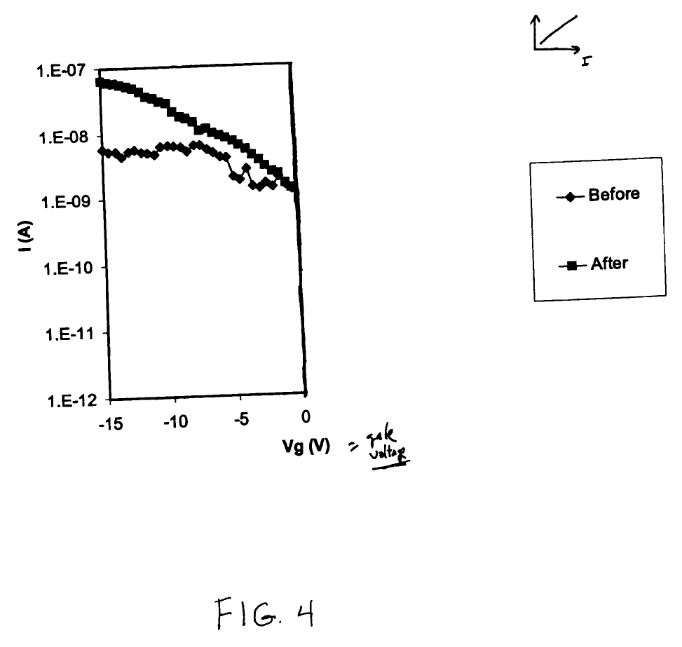

The above approach has been applied to both Tungsten(W)/nanotube contact regions and Titanium Nitride (TiN)/nanotube contact regions, with, W exhibiting lower resistivity after the treatment than the TiN. FIG. 4 shows experimental results for a test structure having a carbon nanotube conductive channel with a 1.4 nm diameter and source and drain electrodes made of Tungsten. The voltage across the Tungsten source and drain electrodes was fixed.

The data of FIG. 4 shows the measured current through the Carbon nanotube conductive channel in response to the fixed voltage across the Tungsten source and drain electrodes. The gate voltage was varied to demonstrate the Carbon nanotube conductive channel current over a wide range of carrier densities within the conductive channel. The data of FIG. 4 shows that the test structure exhibited lower source/drain contact resistance after the oxidizing agent solution treatment because higher currents were sustained through the nanotube for the same combination of source/drain electrode voltage drop and gate voltage. Against comparable transistors without the aforementioned treatment, the total contact resistance was effectively lowered from approximately 10 MΩ to 1 MΩ per tube.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. A method, comprising:
decreasing the resistance of a metal to Carbon nanotube contact region by treating said contact region with an oxidizing agent solution having a pH level within a range of 6.0 to 8.0 inclusive.

2. The method of claim 1 wherein said treating comprises treating said contact region with said oxidizing agent solution for a time period within a range of 1.0 to 5.0 minutes inclusive.

3. The method of claim 1 wherein said metal comprises Tungsten.

4. The method of claim 1 wherein said metal comprises Titanium Nitride.

5. The method of claim 1 wherein said metal is part of a source electrode for a transistor.

6. The method of claim 5 wherein said transistor has a channel that comprises said Carbon nanotube.

7. The method of claim 1 wherein said oxidizing agent solution comprises hydrogen peroxide.

8. The method of claim 1 wherein said oxidizing agent solution does not comprise a chemical selected from the group consisting of:
hydrogen chloride;
nitric acid;
sulfuric acid; and,
phosphoric acid.

9. An apparatus comprising:
a metal to Carbon nanotube contact region comprising a chemical bond between said metal and said Carbon nanotube.

10. The apparatus of claim 9 wherein said metal to Carbon nanotube contact region comprises one or more imperfections in said Carbon nanotube's chirality structure.

11. The apparatus of claim 10 wherein said one or more imperfections were induced to promote said chemical bond's existence.

12. The apparatus of claim 9 wherein said metal comprises Tungsten.

13. The apparatus of claim 9 wherein said metal comprises Titanium Nitride.

14. The method of claim 11 wherein said metal is part of a source electrode for a transistor.

15. The method of claim 14 wherein said transistor has a channel that comprises said Carbon nanotube.

16. A transistor, comprising:
a source electrode comprising metal;
a channel comprising a Carbon nanotube; and,
a contact region between said metal and said Carbon nanotube comprising a chemical bond between said metal and said Carbon nanotube.

17. The apparatus of claim 16 wherein said contact region comprises one or more imperfections in said Carbon nanotube's chirality structure.

18. The apparatus of claim 17 wherein said one or more imperfections were induced to promote said chemical bond's existence.

19. The apparatus of claim 16 wherein said metal comprises Tungsten.

20. The apparatus of claim 16 wherein said metal comprises Titanium Nitride.

21. A method, comprising:
decreasing the resistance of a metal to Carbon nanotube contact region by treating said contact region with an oxidizing agent solution having a pH level within a range of 4.0 to 10.0 inclusive.

22. The method of claim 21 wherein said Carbon nanotube has more than one wall.

23. The method of claim 22 wherein said metal comprises Tungsten.

24. The method of claim 22 wherein said metal comprises Titanium Nitride.
